(19) United States
(12) Patent Application Publication
(10) Pub. No.: US 2026/0101620 A1
(43) Pub. Date: Apr. 9, 2026

(54) DISPLAY APPARATUS

(71) Applicant: AUO Corporation, Hsinchu City (TW)

(72) Inventors: Sheng-Kai Lin, Hsinchu City (TW); Tzu-Chin Huang, Hsinchu City (TW)

(73) Assignee: AUO Corporation, Hsinchu City (TW)

(21) Appl. No.: 19/238,568

(22) Filed: Jun. 16, 2025

(30) Foreign Application Priority Data
Oct. 9, 2024 (TW) 113138474

(51) Int. Cl. H10H 29/37; H10H 29/85; H10H 29/855; H10H 29/856

(52) U.S. Cl. CPC H10H 29/37; H10H 29/8517; H10H 29/8552; H10H 29/856

(57) ABSTRACT

A display apparatus including a driving circuit substrate, a first bank layer, a plurality of light-emitting elements, an opposite substrate, a second bank layer and an encapsulation layer. The first bank layer is disposed on the driving circuit substrate and has a plurality of openings. The plurality of light-emitting elements are disposed in the plurality of openings of the first bank layer. The opposite substrate is disposed opposite to the driving circuit substrate. The second bank layer is disposed on the opposite substrate. The second bank layer includes a plurality of bank blocks. The plurality of bank blocks are separated from each other and have a plurality of gaps. At least one of the plurality of light-emitting elements overlaps at least one of the plurality of gaps. The encapsulation layer is disposed on the plurality of bank blocks and in the plurality of gaps between the plurality of bank blocks.

### CROSS-REFERENCE TO RELATED APPLICATION

This application claims the priority benefit of Taiwan application serial no. 113138474, filed on Oct. 9, 2024. The entirety of the above-mentioned patent application is hereby incorporated by reference herein and made a part of this specification.

### BACKGROUND

### Technical Field

The disclosure relates to a photoelectric apparatus, and more particularly to a display apparatus.

### Description of Related Art

A light-emitting diode display panel includes a driving circuit substrate and a plurality of light-emitting diode elements transferred onto the driving circuit substrate. Inheriting the characteristics of the light-emitting diode, the light-emitting diode display panel has advantages such as power saving, high efficiency, high brightness, and fast response time. In addition, compared with an organic light-emitting diode display panel, the light-emitting diode display panel further has advantages such as easy color tuning, long light-emitting lifetime, and no image retention. Therefore, the light-emitting diode display panel is regarded as a next-generation display technology. Each pixel of the light-emitting diode display panel includes a red sub-pixel, a green sub-pixel, and a blue sub-pixel respectively configured to emit red light, green light, and blue light. However, the light-emitting efficiency of the light-emitting diode element of the red sub-pixel is low, which affects the optical performance of the light-emitting diode display panel.

### SUMMARY

The disclosure provides a display apparatus having high light-emitting efficiency.

A display apparatus of the disclosure includes a driving circuit substrate, a first bank layer, a plurality of light-emitting elements, an opposite substrate, a second bank layer, and an encapsulation layer. The first bank layer is disposed on the driving circuit substrate and has a plurality of openings. The plurality of light-emitting elements are disposed in the plurality of openings of the first bank layer and are electrically connected to the driving circuit substrate. The opposite substrate is disposed opposite to the driving circuit substrate. The second bank layer is disposed on the opposite substrate and is located between the opposite substrate and the first bank layer. The second bank layer includes a plurality of bank blocks. The plurality of bank blocks are separated from each other and have a plurality of gaps. At least one of the plurality of light-emitting elements overlaps at least one of the plurality of gaps. The encapsulation layer is disposed on the plurality of bank blocks and in the plurality of gaps between the plurality of bank blocks, and is located between the plurality of bank blocks and the plurality of light-emitting elements and between the first bank layer and the opposite substrate.

### BRIEF DESCRIPTION OF THE DRAWINGS

FIG. 1 is a bottom view schematic diagram of a display apparatus according to a first embodiment of the disclosure.

FIG. 2 is a cross-sectional schematic diagram of a display apparatus according to the first embodiment of the disclosure.

FIG. 3 is a cross-sectional schematic diagram of a display apparatus according to the first embodiment of the disclosure.

FIG. 4 is a bottom view schematic diagram of a display apparatus according to a second embodiment of the disclosure.

FIG. 5 is a cross-sectional schematic diagram of a display apparatus according to the second embodiment of the disclosure.

FIG. 6 is a cross-sectional schematic diagram of a display apparatus according to the second embodiment of the disclosure.

FIG. 7 is a bottom view schematic diagram of a display apparatus according to a third embodiment of the disclosure.

FIG. 8 is a cross-sectional schematic diagram of a display apparatus according to the third embodiment of the disclosure.

FIG. 9 is a bottom view schematic diagram of a display apparatus according to a fourth embodiment of the disclosure.

FIG. 10 is a cross-sectional schematic diagram of a display apparatus according to the fourth embodiment of the disclosure.

### DESCRIPTION OF THE EMBODIMENTS

Reference will now be made in detail to the exemplary embodiments of the disclosure, examples of which are illustrated in the accompanying drawings. Wherever possible, the same reference numbers are used in the drawings and the description to refer to the same or like parts.

It should be understood that when an element such as a layer, film, region, or substrate is referred to as being “on” or “connected to” another element, it can be directly on or connected to the other element, or intermediate elements may also be present. In contrast, when an element is referred to as being “directly on” or “directly connected to” another element, there are no intervening elements. As used herein, “connection” can refer to physical and/or electrical connection. Furthermore, “electrical connection” or “coupling” can mean that there are other elements between two elements.

As used herein, “about”, “approximately”, or “substantially” includes the stated value and the average value within the acceptable deviation range of the specific value determined by a person of ordinary skill in the art, taking into account the measurement in question and a certain amount of measurement-related error (i.e., the limitation of the measurement system). For example, “about” can mean within one or more standard deviations of the stated value, or within ±30%, ±20%, ±10%, ±5%. Furthermore, “about”, “approximate” or “substantially” used herein can be based on optical properties, etching properties or other properties to select a more acceptable range of deviation or standard deviation, and not one standard deviation can be applied to all properties.

Unless otherwise defined, all terms (including technical and scientific terms) used herein have the same meaning as commonly understood by those of ordinary skill in the art to which the disclosure belongs. It will be further understood that terms such as those defined in commonly used dictionaries should be interpreted as having meanings consistent with the relevant art and the background or context of the disclosure, and should not be interpreted in an idealized or overly formal way, unless otherwise defined in the embodiments of the disclosure.

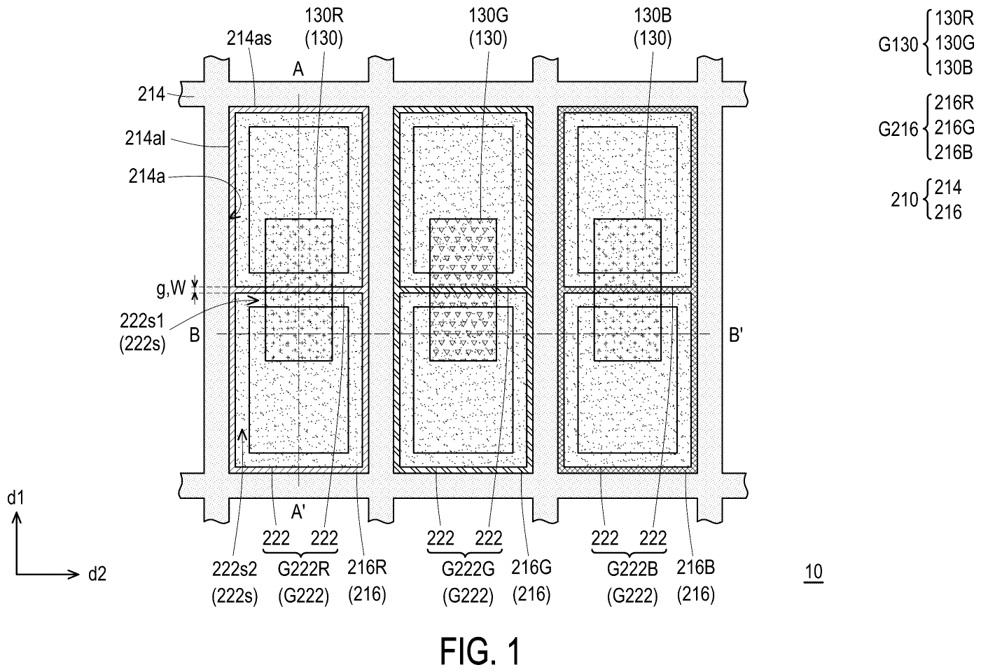

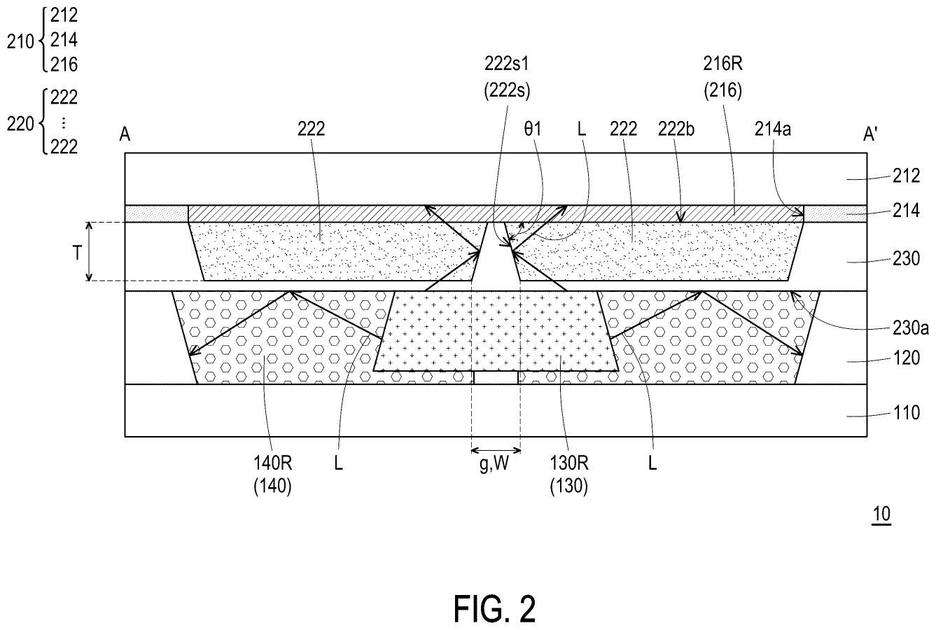

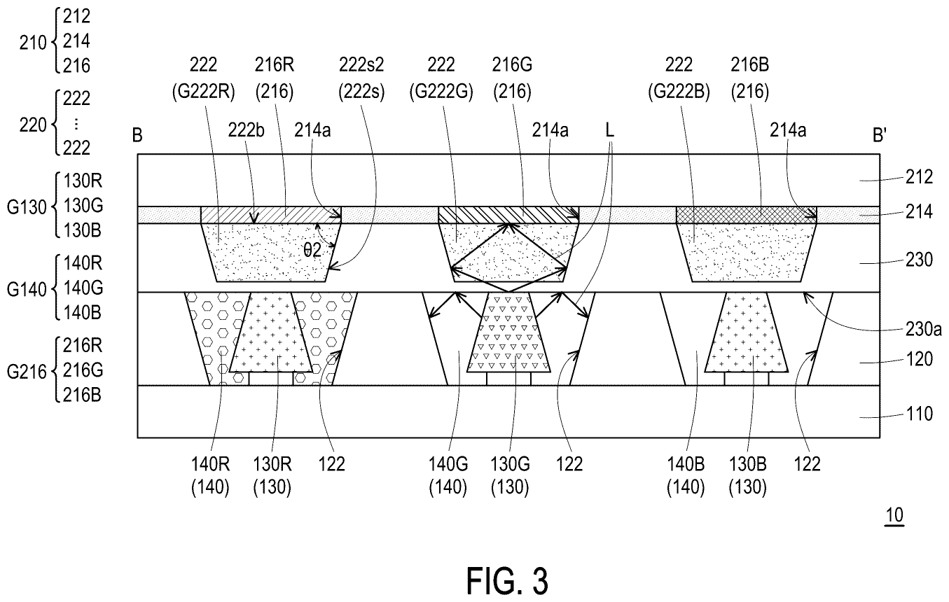

FIG. 1 is a bottom view schematic diagram of a display apparatus according to a first embodiment of the disclosure. FIG. 1 shows a plurality of light-emitting elements 130 and an opposite substrate 210, and other components of a display apparatus 10 are omitted. FIG. 2 is a cross-sectional schematic diagram of the display apparatus according to the first embodiment of the disclosure. FIG. 2 corresponds to a line segment A-A′ in FIG. 1. FIG. 3 is a cross-sectional schematic diagram of the display apparatus according to the first embodiment of the disclosure. FIG. 3 corresponds to a line segment B-B′ in FIG. 1.

Referring to FIGS. 1, 2, and 3, the display apparatus 10 includes a driving circuit substrate 110. The driving circuit substrate 110 has a plurality of sub-pixel driving structures (not shown). In some embodiments, each sub-pixel driving structure may include a sub-pixel driving circuit (not shown) and a pad group (not shown) electrically connected to the sub-pixel driving circuit, wherein the pad group includes at least one pad (not shown). For example, in some embodiments, each sub-pixel driving circuit may include a first transistor (not shown), a second transistor (not shown), and a capacitor (not shown), wherein a first end of the first transistor is electrically connected to a corresponding data line (not shown), a control end of the first transistor is electrically connected to a corresponding scan line (not shown), a second end of the first transistor is electrically connected to a control end of the second transistor, a first end of the second transistor is electrically connected to a corresponding power line (not shown), the capacitor is electrically connected to the second end of the first transistor and the first end of the second transistor, and a second end of the second transistor is electrically connected to a corresponding pad group. However, the disclosure is not limited thereto. In other embodiments, the sub-pixel driving circuit may also be another type of circuit.

Referring to FIGS. 2 and 3, the display apparatus 10 further includes a first bank layer 120, which is disposed on the driving circuit substrate 110 and has a plurality of openings 122. In some embodiments, the first bank layer 120 has high reflectivity. For example, in some embodiments, the first bank layer 120 may be a white reflective structure, but the disclosure is not limited thereto.

Referring to FIGS. 1 and 3, the display apparatus 10 further includes a plurality of light-emitting elements 130, which are disposed in the plurality of openings 122 of the first bank layer 120 and are electrically connected to the driving circuit substrate 110. The plurality of light-emitting elements 130 are respectively bonded to a plurality of pad groups (not shown) of the driving circuit substrate 110. In some embodiments, the plurality of light-emitting elements 130 may be divided into a plurality of light-emitting element groups G130, and each light-emitting element group G130 corresponds to one pixel of the display apparatus 10. Each light-emitting element group G130 may include a first light-emitting element 130R, a second light-emitting element 130G, and a third light-emitting element 130B. In some embodiments, the first light-emitting element 130R, the second light-emitting element 130G, and the third light-emitting element 130B may respectively be a plurality of light-emitting diode elements configured to emit a first color light, a second color light, and a third color light. For example, in some embodiments, the first color light, the second color light, and the third color light may respectively be blue light, green light, and blue light, but the disclosure is not limited thereto.

Referring to FIG. 3, in some embodiments, the display apparatus 10 may optionally further include a plurality of optical structures 140, which are respectively filled in the plurality of openings 122 of the first bank layer 120 and cover the plurality of light-emitting elements 130. In some embodiments, the plurality of optical structures 140 may be divided into a plurality of optical structure groups G140, and each optical structure group G140 may include a first optical structure 140R, a second optical structure 140G, and a third optical structure 140B that respectively cover the first light-emitting element 130R, the second light-emitting element 130G, and the third light-emitting element 130B. In some embodiments, the first optical structure 140R is, for example, a color conversion structure, and the color conversion structure may convert the first color light emitted by the first light-emitting element 130R into a fourth color light. For example, in some embodiments, the color conversion structure may convert the blue light emitted by the first light-emitting element 130R into red light. In some embodiments, the second optical structure 140G and the third optical structure 140B are, for example, a plurality of light-transmissive structures, and the second color light emitted by the second light-emitting element 130G and the third color light emitted by the third light-emitting element 130B may respectively pass through the plurality of light-transmissive structures and substantially not change their colors.

Referring to FIGS. 1 and 3, the display apparatus 10 further includes an opposite substrate 210, which is disposed opposite to the driving circuit substrate 110. In some embodiments, the opposite substrate 210 may include a transparent base 212, a light-shielding pattern layer 214 disposed on the transparent base 212, and a plurality of color filter patterns 216 respectively located in a plurality of openings 214a of the light-shielding pattern layer 214. In some embodiments, the plurality of openings 214a of the light-shielding pattern layer 214 are respectively located above the plurality of openings 122 of the first bank layer 120. That is, the physical body of the first bank layer 120 is disposed under the physical body of the light-shielding pattern layer 214. In some embodiments, the plurality of color filter patterns 216 may be divided into a plurality of color filter pattern groups G216. Each color filter pattern group G216 may include a first color filter pattern 216R, a second color filter pattern 216G, and a third color filter pattern 216B that are different in color. In some embodiments, the first color filter pattern 216R, the second color filter pattern 216G, and the third color filter pattern 216B are, for example, respectively a red filter pattern, a green filter pattern, and a blue filter pattern.

Referring to FIGS. 1 and 2, the display apparatus 10 further includes a second bank layer 220, which is disposed on the opposite substrate 210 and is located between the opposite substrate 210 and the first bank layer 120. The second bank layer 220 includes a plurality of bank blocks 222. The plurality of bank blocks 222 are separated from each other and have a plurality of gaps g. At least one of the plurality of light-emitting elements 130 overlaps at least one of the plurality of gaps g. For example, in some embodiments, a width W of a gap g may be greater than 0 μm and less than or equal to 5 μm, but the disclosure is not limited thereto.

Referring to FIGS. 1 and 3, in some embodiments, the plurality of bank blocks 222 may be divided into a plurality of bank block groups G222, and each bank block group G222 includes at least two bank blocks 222. The at least two bank blocks 222 of each bank block group G222 overlap a corresponding color filter pattern 216. In some embodiments, the plurality of bank block groups G222 may include a first bank block group G222R, a second bank block group G222G, and a third bank block group G222B, which respectively overlap the first color filter pattern 216R, the second color filter pattern 216G, and the third color filter pattern 216B. A quantity of the plurality of bank blocks 222 of the first bank block group G222R, a quantity of the plurality of bank blocks 222 of the second bank block group G222G, and a quantity of the plurality of bank blocks 222 of the third bank block group G222B may be the same or different. For example, in some embodiments, the quantity of the plurality of bank blocks 222 of the first bank block group G222R, the quantity of the plurality of bank blocks 222 of the second bank block group G222G, and the quantity of the plurality of bank blocks 222 of the third bank block group G222B may optionally be the same (for example, all of the quantities are 2), but the disclosure is not limited thereto.

Referring to FIG. 1, in some embodiments, each opening 214a of the light-shielding pattern layer 214 may have a long side 214al and a short side 214as adjacent to the long side 214al. In some embodiments, the plurality of bank blocks 222 of the first bank block group G222R may be arranged in a direction d1 parallel to the long side 214al and be separated from each other. In some embodiments, the plurality of bank blocks 222 of the second bank block group G222G may be arranged in the direction d1 parallel to the long side 214al and be separated from each other. In some embodiments, the plurality of bank blocks 222 of the third bank block group G222B may be arranged in the direction d1 parallel to the long side 214al and be separated from each other.

Referring to FIGS. 1, 2, and 3, each bank block 222 has a plurality of side walls 222s inclined relative to the opposite substrate 210. The plurality of side walls 222s of each bank block 222 include a first side wall 222sl and a second side wall 222s2 adjacent to the first side wall 222s1. Each bank block 222 further has a bottom surface 222b facing away from the driving circuit substrate 110. In some embodiments, in a bottom view of the display apparatus 10, the first side wall 222sl overlaps a corresponding one of the light-emitting elements 130, the second side wall 222s2 is located outside the light-emitting element 130, a first angle θ1 is provided between the first side wall 222sl and the bottom surface 222b, a second angle θ2 is provided between the second side wall 222s2 and the bottom surface 222b, and the second angle θ2 is greater than the first angle θ1. For example, in some embodiments, the first angle θ1 may be in a range of 44 degrees to 74 degrees, and the second angle θ2 may be in a range of 72 degrees to 78 degrees, but the disclosure is not limited thereto.

Referring to FIGS. 2 and 3, the display apparatus 10 further includes an encapsulation layer 230, which is disposed on the plurality of bank blocks 222 and in the plurality of gaps g between the plurality of bank blocks 222, and is located between the plurality of bank blocks 222 and the plurality of light-emitting elements 130 and between the first bank layer 120 and the opposite substrate 210. In some embodiments, the encapsulation layer 230 may entirely cover the opposite substrate 210 and the plurality of bank blocks 222 of the second bank layer 220. The material of the encapsulation layer 230 and the material of the second bank layer 220 may both be light-transmissive materials.

It is worth mentioning that a light beam L emitted from the light-emitting element 130 may be reflected by the side walls 222s of the bank blocks 222 of the second bank layer 220 to increase the probability of light emission, thereby enhancing the brightness of the display apparatus 10. In addition, in some embodiments, the encapsulation layer 230 has a surface 230a facing the plurality of light-emitting elements 130, and the light beam L emitted from the light-emitting element 130 may undergo total reflection on the surface 230a and be reflected back into the opening 122 of the first bank layer 120 to be reused. Thereby, the probability of light emission of the light beam L can also be increased, and the brightness of the display apparatus 10 can be further enhanced.

Referring to FIG. 2, in some embodiments, a refractive index of the second bank layer 220 may be greater than a refractive index of the encapsulation layer 230. In some embodiments, the greater the difference in refractive index between the second bank layer 220 (or the bank blocks 222) and the encapsulation layer 230, the greater a thickness T of the second bank layer 220 (or the height of the bank blocks 222), and the greater the first angle θ1, which is more helpful for enhancing the brightness of the display apparatus 10. For example, in some embodiments, the refractive index of the second bank layer 220 may be in a range of 1.63 to 1.73, the refractive index of the encapsulation layer 230 may be in a range of 1.21 to 1.43, and the thickness T of the second bank layer 220 may be in a range of 8 μm to 9 μm, but the disclosure is not limited thereto. It should be noted that in the following embodiments, the same reference numerals and

some contents from the foregoing embodiments are used. The same or similar elements are denoted by the same reference numerals, and the descriptions of the same technical contents are omitted. For the omitted parts, reference may be made to the foregoing embodiments, and the following embodiments will not repeat them.

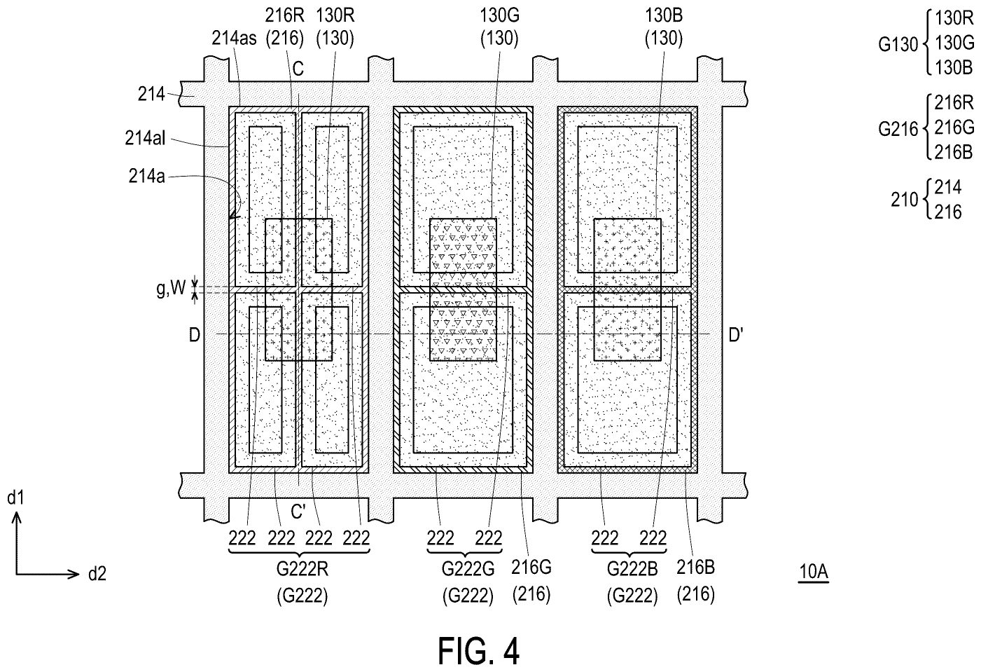

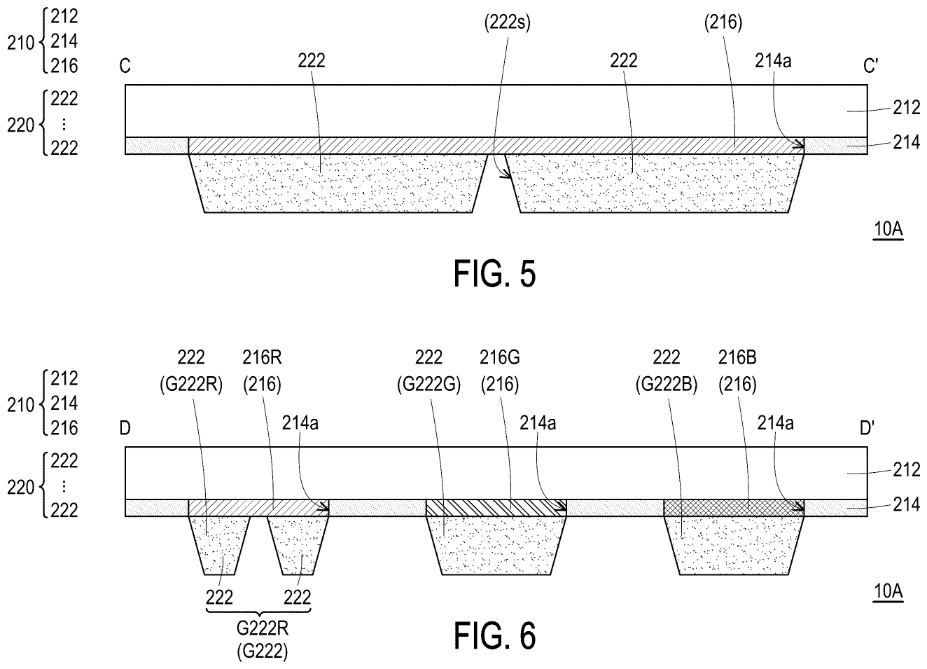

FIG. 4 is a bottom view schematic diagram of a display apparatus according to a second embodiment of the disclosure. FIG. 4 shows a plurality of light-emitting elements 130 and the opposite substrate 210, and other components of a display apparatus 10A are omitted. FIG. 5 is a cross-sectional schematic diagram of a display apparatus according to the second embodiment of the disclosure. FIG. 5 corresponds to a line segment C-C′ in FIG. 4. FIG. 6 is a cross-sectional schematic diagram of a display apparatus according to the second embodiment of the disclosure. FIG. 6 corresponds to a line segment D-D′ in FIG. 4. FIGS. 5 and 6 show the opposite substrate 210 and the plurality of bank blocks 222, and other components of the display apparatus 10A are omitted.

The display apparatus 10A of the second embodiment of FIGS. 4, 5, and 6 is similar to the display apparatus 10 of the first embodiment of FIGS. 1, 2, and 3. The difference between the two is that in the second embodiment of FIGS. 4, 5, and 6, a quantity of the plurality of bank blocks 222 of the first bank block group G222R is different from a quantity of the plurality of bank blocks 222 of the second bank block group G222G. Referring to FIG. 4, in this embodiment, the quantity of the plurality of bank blocks 222 of the first bank block group G222R may be greater than the quantity of the plurality of bank blocks 222 of the second bank block group G222G. That is, a greater number of bank blocks 222 may overlap the first light-emitting element 130R, so as to improve a light-emitting efficiency of the first light-emitting element 130R.

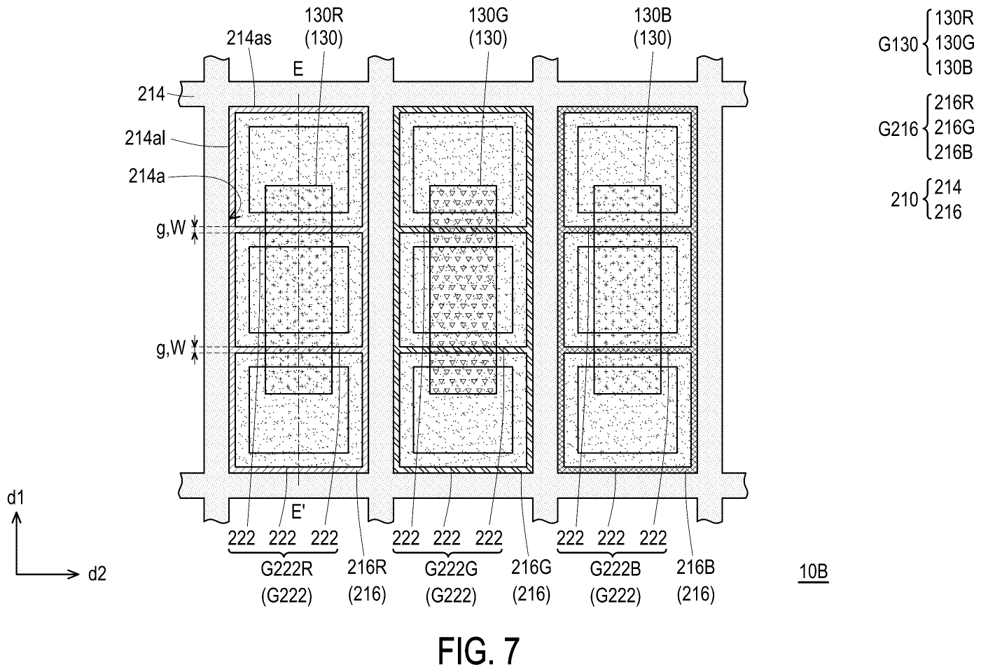

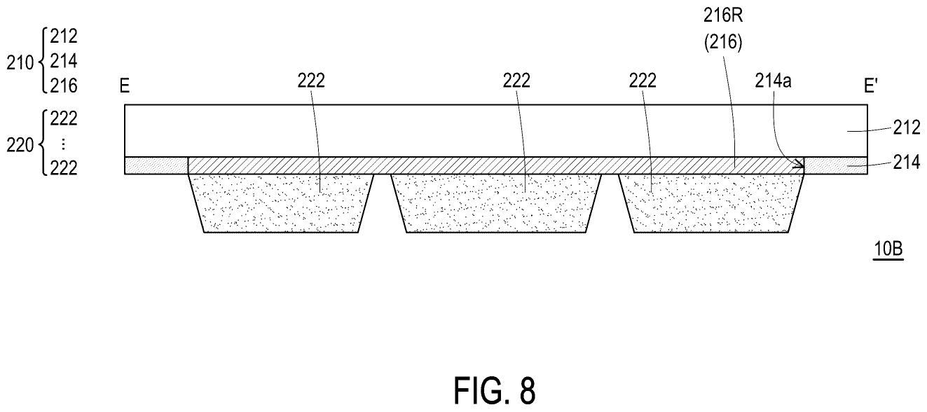

FIG. 7 is a bottom view schematic diagram of a display apparatus according to a third embodiment of the disclosure. FIG. 7 shows a plurality of light-emitting elements 130 and the opposite substrate 210, and other components of a display apparatus 10B are omitted. FIG. 8 is a cross-sectional schematic diagram of a display apparatus according to the third embodiment of the disclosure. FIG. 8 corresponds to a line segment E-E′ in FIG. 7. FIG. 8 shows the opposite substrate 210 and the plurality of bank blocks 222, and other components of the display apparatus 10B are omitted.

The display apparatus 10B of the third embodiment of FIGS. 7 and 8 is similar to the display apparatus 10 of the first embodiment of FIGS. 1 and 2. In the first embodiment of FIGS. 1 and 2 and the third embodiment of FIGS. 7 and 8, the plurality of bank blocks 222 of each bank block group G222 are arranged in the direction d1 parallel to the long side 214al and are separated from each other. The difference between the display apparatus 10B of the third embodiment of FIGS. 7 and 8 and the display apparatus 10 of the first embodiment of FIGS. 1 and 2 is that each bank block group G222 of the third embodiment of FIGS. 7 and 8 includes three bank blocks 222, while each bank block group G222 of the first embodiment of FIGS. 1 and 2 includes two bank blocks 222.

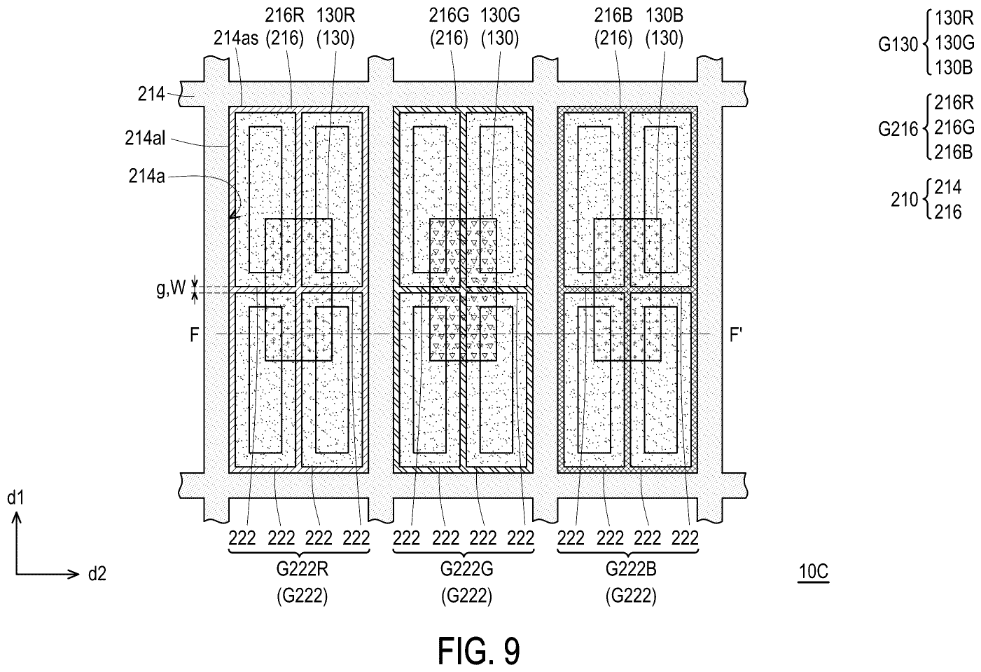

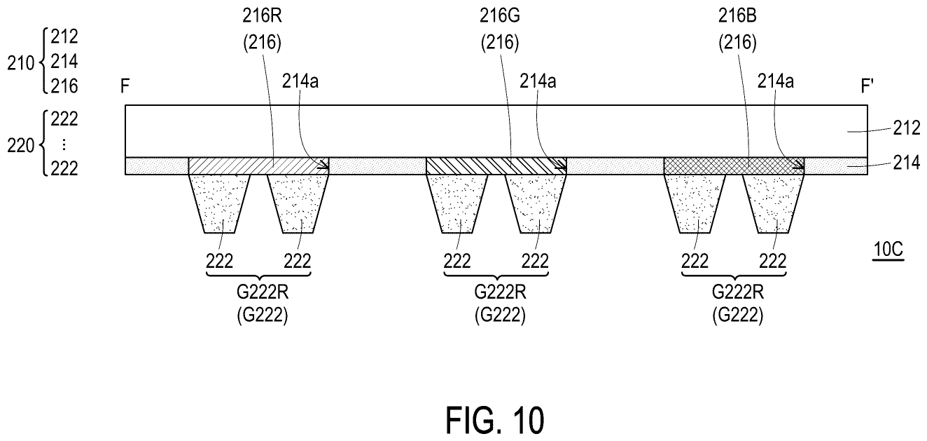

FIG. 9 is a bottom view schematic diagram of a display apparatus according to a fourth embodiment of the disclosure. FIG. 9 shows a plurality of light-emitting elements 130 and the opposite substrate 210, and other components of a display apparatus 10C are omitted. FIG. 10 is a cross-sectional schematic diagram of a display apparatus according to the fourth embodiment of the disclosure. FIG. 10 corresponds to a line segment F-F′ in FIG. 9. FIG. 10 shows the opposite substrate 210 and the plurality of bank blocks 222, and other components of the display apparatus 10C are omitted.

The display apparatus 10C of the fourth embodiment of FIGS. 9 and 10 is similar to the display apparatus 10 of the first embodiment of FIGS. 1 and 2. The difference between the two is that in the embodiment of FIGS. 9 and 10, each bank block group G222 includes a plurality of bank blocks 222 that are arranged in an array in the direction d1 and a direction d2. Referring to FIGS. 9 and 10, in this embodiment, a part of the plurality of bank blocks 222 of each bank block group G222 are arranged in the direction d1 parallel to the long side 214al and are separated from each other, and a part of the plurality of bank blocks 222 of each bank block group G222 are arranged in the direction d2 parallel to the short side 214as and are separated from each other.

What is claimed is:

1. A display apparatus, comprising:
a driving circuit substrate;
a first bank layer, disposed on the driving circuit substrate and having a plurality of openings;
a plurality of light-emitting elements, disposed in the plurality of openings of the first bank layer and electrically connected to the driving circuit substrate;
an opposite substrate, disposed opposite to the driving circuit substrate;
a second bank layer, disposed on the opposite substrate and located between the opposite substrate and the first bank layer, wherein the second bank layer comprises a plurality of bank blocks, the plurality of bank blocks are separated from each other and have a plurality of gaps, and at least one of the plurality of light-emitting elements overlaps at least one of the plurality of gaps; and
an encapsulation layer, disposed on the plurality of bank blocks and in the plurality of gaps between the plurality of bank blocks, wherein the encapsulation layer is located between the plurality of bank blocks and the plurality of light-emitting elements and between the first bank layer and the opposite substrate.

2. The display apparatus according to claim 1, wherein a refractive index of the second bank layer is greater than a refractive index of the encapsulation layer.

3. The display apparatus according to claim 1, wherein the opposite substrate comprises a transparent base, a light-shielding pattern layer, and a plurality of color filter patterns, the light-shielding pattern layer is disposed on the transparent base and has a plurality of openings, the plurality of color filter patterns are respectively disposed in the plurality of openings, the plurality of bank blocks are divided into a plurality of bank block groups, each bank block group comprises at least two bank blocks of the plurality of bank blocks, and the at least two bank blocks of the each bank block group overlap a corresponding one of the plurality of color filter patterns.

4. The display apparatus according to claim 3, wherein the plurality of color filter patterns comprise a first color filter pattern and a second color filter pattern different in color, the plurality of bank block groups comprise a first bank block group and a second bank block group respectively overlapping the first color filter pattern and the second color filter pattern, and a quantity of the plurality of bank blocks of the first bank block group is different from a quantity of the plurality of bank blocks of the second bank block group.

5. The display apparatus according to claim 4, wherein the first color filter pattern and the second color filter pattern are respectively a red filter pattern and a green filter pattern, and the quantity of the plurality of bank blocks of the first bank block group is greater than the quantity of the plurality of bank blocks of the second bank block group.

6. The display apparatus according to claim 3, wherein one of the plurality of openings of the light-shielding pattern layer has a long side and a short side adjacent to the long side, the plurality of bank block groups comprise a first bank block group, and the plurality of bank blocks of the first bank block group are arranged in a direction parallel to the long side and are separated from each other.

7. The display apparatus according to claim 3, wherein one of the plurality of openings of the light-shielding pattern layer has a long side and a short side adjacent to the long side, the plurality of bank block groups comprise a first bank block group, and the plurality of bank blocks of the first bank block group are arranged in a direction parallel to the short side and are separated from each other.

8. The display apparatus according to claim 1, wherein one of the plurality of bank blocks has a first side wall and a second side wall adjacent to the first side wall; in a bottom view of the display apparatus, the first side wall overlaps a corresponding one of the plurality of light-emitting elements, and the second side wall is located outside the light-emitting element; the one of the plurality of bank blocks has a bottom surface facing away from the driving circuit substrate, a first angle is provided between the first side wall and the bottom surface, a second angle is provided between the second side wall and the bottom surface, and the second angle is greater than the first angle.

9. The display apparatus according to claim 8, wherein the first angle is in a range of 44 degrees to 74 degrees, and the second angle is in a range of 72 degrees to 78 degrees.

10. The display apparatus according to claim 1, wherein a width of one of the plurality of gaps is greater than 0 μm and less than or equal to 5 μm.

11. A display apparatus, comprising:
a driving circuit substrate;
a first bank layer, disposed on the driving circuit substrate and having a plurality of openings;
a plurality of light-emitting elements, disposed in the plurality of openings of the first bank layer and electrically connected to the driving circuit substrate;
an opposite substrate, disposed opposite to the driving circuit substrate;
a second bank layer, disposed on the opposite substrate and located between the opposite substrate and the first bank layer, wherein the second bank layer comprises a plurality of bank blocks; and
an encapsulation layer, disposed on the plurality of bank blocks and located between the plurality of bank blocks and the plurality of light-emitting elements and between the first bank layer and the opposite substrate; wherein
a refractive index of the second bank layer is greater than a refractive index of the encapsulation layer.

12. The display apparatus according to claim 11, wherein the opposite substrate comprises a transparent base, a light-shielding pattern layer, and a plurality of color filter patterns, the light-shielding pattern layer is disposed on the transparent base and has a plurality of openings, the plurality of color filter patterns are respectively disposed in the plurality of openings, the plurality of bank blocks are divided into a plurality of bank block groups, each bank block group comprises at least two bank blocks of the plurality of bank blocks, and the at least two bank blocks of the each bank block group overlap a corresponding one of the plurality of color filter patterns.

13. The display apparatus according to claim 12, wherein the plurality of color filter patterns comprise a first color filter pattern and a second color filter pattern different in color, the plurality of bank block groups comprise a first bank block group and a second bank block group respectively overlapping the first color filter pattern and the second color filter pattern, and a quantity of the plurality of bank blocks of the first bank block group is different from a quantity of the plurality of bank blocks of the second bank block group.

14. The display apparatus according to claim 13, wherein the first color filter pattern and the second color filter pattern are respectively a red filter pattern and a green filter pattern, and the quantity of the plurality of bank blocks of the first bank block group is greater than the quantity of the plurality of bank blocks of the second bank block group.

15. The display apparatus according to claim 12, wherein one of the plurality of openings of the light-shielding pattern layer has a long side and a short side adjacent to the long side, the plurality of bank block groups comprise a first bank block group, and the plurality of bank blocks of the first bank block group are arranged in a direction parallel to the long side and are separated from each other.
